(19) United States
(12) Patent Application Publication
(10) Pub. No.: US 2013/0046502 A1
(43) Pub. Date: Feb. 21, 2013

(54) MOTHERBOARD TEST DEVICE

(71) Applicants: Hao ZHANG, Shenzhen City (CN); Yu-Mei LI, Shenzhen City (CN); Hui LI, Shenzhen City (CN)

(72) Inventors: Hao ZHANG, Shenzhen City (CN); Yu-Mei LI, Shenzhen City (CN); Hui LI, Shenzhen City (CN)

(73) Assignees: HON HAI PRECISION INDUSTRY CO., LTD., Tu-Cheng (TW); HON FU JIN PRECISION INDUSTRY(ShenZhen) CO., LTD., Shenzhen City (CN)

(21) Appl. No.: 13/303,159

(22) Filed: Nov. 23, 2011

(30) Foreign Application Priority Data
Aug. 16, 2011 (CN) 201110234431.0

(51) Int. Cl. G06F 19/00; G01R 31/00

(52) U.S. Cl. 702/117

(57) ABSTRACT

A test device for testing a motherboard includes a connector, a processor, and a controller. The motherboard includes a slot including a sleep unit and a wake port. The connector is inserted into the slot to make an electrical connection with the motherboard. The processor includes a first pin connected to the wake port, a second pin connected to the sleep unit, and a control port sending control signals to the first pin and the second pin. The controller includes a first control module, a second control module, and a timer. The timer is programmed with at least two time points. Wherein the first control module and the second control module respectively send signals to the control port at each time point, to control the motherboard to enter the sleep mode and wake mode by turns.

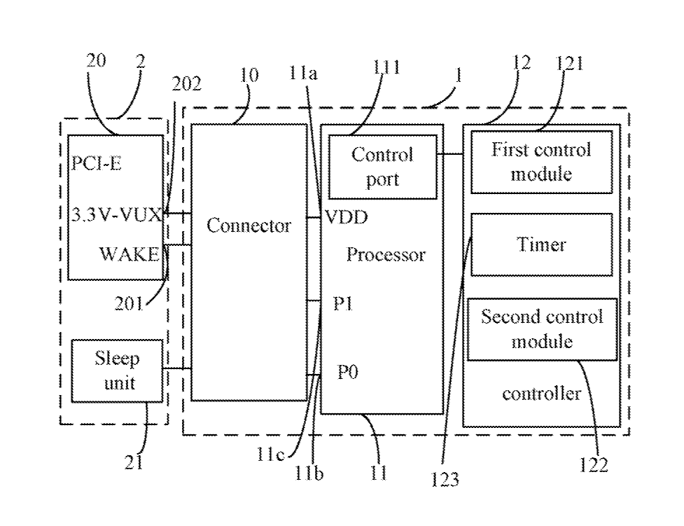

### BACKGROUND

1. Technical Field

The present disclosure relates to test devices and, particularly, to a test device for testing a motherboard ability to switch between a sleep mode and a wake mode.

2. Description of Related Art

Most computers can enter a sleep mode when not used for a preset time, and recover to a wake mode when receiving user input. The sleep mode and wake mode are provided by the motherboard of the computers. During manufacture, motherboards will be tested to determine whether the motherboard can successfully switch between a sleep mode and a wake mode. A conventional method of testing the motherboards is to first connect the motherboards to a test computer through a network card and cable, and then send signal to the motherboard through the test computer, to switch the motherboard between the sleep mode and wake mode. And signals from the motherboard are sent to an oscilloscope and analyzed to determine whether the motherboard successfully switches the modes. Although the conventional test method can satisfy basic requirements, a new test device is still required that relies on less equipment and is therefore less expensive.

### BRIEF DESCRIPTION OF THE DRAWINGS

The components of the drawing are not necessarily drawn to scale, the emphasis instead being placed upon clearly illustrating the principles of the present disclosure.

The drawing is a schematic view of a motherboard test device in accordance with an exemplary embodiment.

### DETAILED DESCRIPTION

The embodiments of the present disclosure are described in detail, with reference to the accompanying drawing.

Referring to the drawing, a schematic view of a test device 1 in accordance with an exemplary embodiment is shown. The test device 1 is used to test a motherboard 2 to determine whether the motherboard 2 can switch between power modes such as a sleep mode and a wake mode. The motherboard 2 includes a slot 20 and a sleep unit 21. In the embodiment, the slot 20 is a PCI-Express (PCI-E) slot. The slot 20 includes a wake port 201 and a power supply output port 202.

The test device 1 includes a connector 10, a processor 11, and a controller 12. The connector 10 can be inserted into the slot 20 of the motherboard 2 to make an electrical connection with the motherboard 2.

The processor 11 includes at least one power supply input port 11a, a first pin 11c, a second pin 11b, and a control port 111. When the connector 10 is inserted into the slot 20, the power supply input port 11a is electrically connected to the power supply output port 202 of the slot 20. Power can then be supplied to the test device 1 from motherboard 2. The first pin 11c is electrically connected to the wake port 201 of the slot 20. The second pin 11b is electrically connected to the sleep unit 21. The control port 101 is used to send a control signal to the first pin 11c and the second pin 11b.

The controller 12 is electrically connected to the control port 111 of the processor 11. The controller 12 includes a first control module 121, a second control module 122, and a timer 123. The first control module 121 and the second control module 122 are electrically connected to the timer 123.

The timer 123 can be programmed to have several time points, such as a first time point t₁, a second time point t₂, a third time point t₃, a fourth time point t₄, . . . , and a time point tₙ. In the embodiment, the number of the time points and the interval between two adjacent time points can be set according to need. The first control module 121 and the second control module 122 are set to send a signal to the control port 111 at each time point, to repeatedly switch the motherboard between the sleep mode and the wake mode.

In detail, when the first time point t₁ is reached, the first control module 121 sends a signal to the control port 111 of the processor 11. The control port 111 sends a low level signal via the second pin 11b to the sleep unit 21, to control the motherboard 2 to enter the sleep mode. When the second time point t₂ is reached, the second control module 122 sends a signal to the control port 111 of the processor 11. The control port 111 sends a high level signal via the first pin 11c to the wake port 201, to control the motherboard 2 to enter the wake mode. When the third time point t₃ is reached, the motherboard 2 will be controlled to enter the sleep mode as controlled at time point t₁. When the fourth time point t₄ is reached, the motherboard 2 will be controlled to enter the wake mode as at time point t₂. That is, the motherboard 2 will be controlled to enter the sleep mode and the wake mode by turns. By using the test device 1, devices for testing the switching between the sleep mode and the wake mode, such as a test card and a computer can be omitted.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A test device for testing a motherboard between a sleep mode and a wake mode, the motherboard comprising a slot and a wake port, the slot comprising a sleep unit, the test device comprising:
a connector configured to be inserted into the slot of the motherboard to make an electrical connection with the motherboard;
a processor comprising a first pin, a second pin, and a control port, when the connector is inserted into the slot of the motherboard, the first pin being electrically connected to the wake port of the motherboard, and the second pin being electrically connected to the sleep unit of the motherboard, the control port being configured to send control signals to the first pin and the second pin; and
a controller electrically connected to the control port of the processor, the controller comprising a first control module, a second control module, and a timer, the first control module and the second control module being electrically connected to the timer, the timer being programmed to have at least two time points;
wherein the first control module sends a signal to the control port when one of the at least two time points is reached, to control the motherboard to enter the sleep mode; and the second control module sends a signal to the control port when the another one of the at least two time points is reached, to control the motherboard to enter the wake mode to control the motherboard to enter the sleep mode and wake mode by turns.

2. The test device as described in claim 1, wherein the slot further comprises a power supply output port, the processor comprises a power supply input port to be electrically connected to the power supply output port, thus power can be supplied to the test device from the motherboard.

3. The test device as described in claim 1, wherein when the first control module sends a signal to the control port, the control port sends a low level signal via the second pin to the sleep unit, to control the motherboard to enter the sleep mode.

4. The test device as described in claim 1, wherein when the second control module sends a signal to the control port, the control port sends a high level signal via the first pin to the wake port, to control the motherboard to enter the wake mode.

5. The test device as described in claim 1, wherein the slot is a PCI-E slot.
